(19) United States
(12) Patent Application Publication
(10) Pub. No.: US 2016/0126308 A1
(43) Pub. Date: May 5, 2016

(54) SUPER-JUNCTION EDGE TERMINATION FOR POWER DEVICES

(71) Applicant: Global Power Technologies Group, Inc., Lake Forest, CA (US)

(72) Inventor: Rahul Radhakrishnan, Lake Forest, CA (US)

(21) Appl. No.: 14/930,424

(22) Filed: Nov. 2, 2015

Related U.S. Application Data
(60) Provisional application No. 62/073,932, filed on Oct. 31, 2014.

(51) Int. Cl. H01L 29/06; H01L 29/861; H01L 29/16

(52) U.S. Cl. CPC H01L 29/0634; H01L 29/1608; H01L 29/861

(57) ABSTRACT

A semiconductor power device includes a junction termination extension (JTE) region that is defined by a gradually reducing width extending towards a periphery of the semiconductor device. In one advantageous aspect, the JTE design achieves a flat electric field profile across the JTE region. In another advantageous aspect, area efficiency of implementations can be increased, thereby reducing cost and complexity of fabrication.

### CROSS REFERENCE TO RELATED APPLICATIONS

This patent document claims the benefit of U.S. Provisional Patent Application No. 62/073,932, filed on Oct. 31, 2014, entitled “SUPER-JUNCTION EDGE TERMINATION FOR POWER DEVICES”. The entire content of the before-mentioned patent application is incorporated by reference as part of the disclosure of this document.

### TECHNICAL FIELD

This patent document relates to semiconductor technologies.

### BACKGROUND

Power devices require structures for electric field termination schemes to avoid early breakdown at junction-edges. The termination schemes are made to lessen the effects of field crowding at the edge of the device, since the electric field can become many times higher at the corners than in the center of a junction between depletion regions of opposite carrier types and the field crowding is worse at the junction corners in the three-dimensional case. To avoid early breakdown at the edge, the electric field needs to be distributed more evenly over the surface, which costs large area. The currently available termination schemes occupy chip area beyond the active current carrying region which increases the semiconductor material required to fabricate the device.

### SUMMARY

Techniques, systems, and devices are described for designing and fabricating a junction termination extension region in a semiconductor device such as a power device.

In one example aspect, a disclosed semiconductor power device includes a junction termination extension (JTE) region that is defined by a gradually reducing width extending towards a periphery of the semiconductor device. In some implementations, the gradually reducing width is defined by a non-linear tapering towards the periphery. In some implementations, a first doping charge of the JTE region is opposite to that of a doping charge of an epi region of the semiconductor device. In some implementations, the gradual reducing is defined by a linear tapering towards the periphery. In some implementations, the gradual reducing results in a lowering of average charge at a particular distance from an edge of an anode of the semiconductor device, wherein a relation between the average charge and the particular distance is a continuously decreasing function of the particular distance. In some implementations, a substrate of the semiconductor device comprises Silicon Carbide (SiC).

In another aspect, a semiconductor device is provided to include a substrate; and an epitaxial layer formed over the substrate and having a first conductivity, the epitaxial layer including different portions electrically connected to a cathode and an anode, respectively; and a JTE region formed over the epitaxial layer and extending away from the anode, the JTE region having a decreasing width as being away from the anode. In some implementations, the semiconductor device further comprises: a doping region having a second conductivity and located in the epitaxial layer to be electrically contacted with the cathode. In some implementations, the JTE region has a gradually lowering doping concentration toward a periphery of the semiconductor device. In some implementations, the substrate includes SiC. In some implementations, the JTE region provides a substantially flat electric field profile. In some implementations, the JTE region has a part having the first conductivity and another part having a second conductivity. In some implementations, the JTE region allows electric fields at a surface of the anode to have peaks at locations differently located from an edge of the anode. In some implementations, the semiconductor device further includes a field stop region formed over the epitaxial layer and located at a periphery of the semiconductor device.

In another aspect, a semiconductor device is provided to comprise: a substrate; an epitaxial layer formed over the substrate and having a first conductivity; a doping region formed in the epitaxial layer and having a second conductivity with a first implant dose; a JTE region formed over the epitaxial layer and having a second implant dose, the second implant dose obtained from the first implant dose. In some implementations, the second implant dose is obtained by scaling the first implant dose based on a dimension of the JTE region. In some implementations, the dimension of the JTE region includes a width or a pitch. In some implementations, the JTE region has a decreasing width as being away from the doping region. In some implementations, the JTE region has a gradually lowering doping concentration as being away from the doping region. In some implementations, the semiconductor device further comprises: a field stop region formed over the epitaxial layer and located at a periphery of the semiconductor device.

In one advantageous aspect, the JTE design achieves a flat electric field profile across the JTE region. In another advantageous aspect, area efficiency of implementations can be increased, thereby reducing cost and complexity of fabrication. The semiconductor device may comprise Silicon or Silicon Carbide (SiC) substrate.

The above and other aspects of the disclosed technology and their implementations are described in greater detail in the drawings, the description and the claims.

### BRIEF DESCRIPTION OF THE DRAWINGS

The patent or application file contains at least one drawing executed in color. Copies of this patent or patent application publication with color drawings will be provided by the Office upon request and payment of the necessary fee.

FIG. 1 shows an example of a power device with an edge termination scheme using 3D field coupling structure.

FIG. 2 shows three cut planes C1 to C3 in the structure used for TCAD simulation.

FIGS. 3A, 3B and 3C show respective simulation results for the cut planes C1 to C3 of FIG. 2. FIG. 3A shows the section from C1, which passes through the center of the p-well region. FIG. 3C shows the section from C3, which bisects neighboring C1 cuts. FIG. 3B shows the section from C2 which bisects C1 and C3 cuts.

FIG. 4 shows a graph of a surface electric field along the cut planes C1 to C3 of FIG. 2. The graphs from C1, C2 and C3 are labelled 410, 420 and 430 respectively.

FIG. 5 shows a top view of an example of a super-JTE structure with p-well region (extending in blue from the anode region) and a n-epi region (orange).

FIG. 6 shows a top view of an example of a super-JTE structure with p-well region (blue), n-epi region (orange) and n+ filed stop region (red).

FIG. 7 shows an exemplary JTE design for corner regions.

FIG. 8 shows various test designs for super JTE structures, with dimension labels defined in FIG. 6.

FIG. 9 shows a comparison of chip savings of 3D JTE v/s floating filed rings

### DETAILED DESCRIPTION

Techniques, systems, and devices are described for super junction edge termination of power devices. Some implementations provide a new edge termination scheme using 3D field coupling which can achieve desired electric field termination profile while minimizing a chip area.

A conventional power semiconductor device may begin to break down and allow non-trivial amounts of leakage current to flow at a voltage that is lower than the design breakdown voltage of the device. In particular, leakage current may begin to flow at the edges of the active region that has a p-n junction and/or a Schottky junction. In order to reduce the increased leakage current and/or avoid early breakdown at junction-edges, electric field termination regions are provided near an active p-n junction to spread the electric field over a greater area. Various edge-termination schemes are available, which include field rings, junction termination extension (JTE), space-modulated JTE implementations. The field ring scheme employs highly doped field rings which spread surface potential drop over a wider area. In this case, the electric field profile is highly non-uniform leading to poor area efficiency. The field ring scheme is not very sensitive to implant dose but very sensitive to spacing between implants.

The JTE scheme extends an implanted region of appropriate dopant concentration and depth outward from the edge of the junction such that the blocking voltage at which the JTE region is just fully depleted is the same as that at which avalanche breakdown starts at some point in the device edge. For example, the JTE scheme is used to alter the surface electric field at the edge based upon selectively adding charge to the p-n junction or Schottky junction of the device. Such a JTE design is capable of achieving edge-breakdown at >90% of parallel plane breakdown voltage but it is sensitive to the implant concentration and typically JTE width is more than 5 times the epitaxial thickness in various implementations. The latter is because electric field peaks both at the inner and outer edges of the JTE while falling off quickly in the middle. The blocked voltage, being the integral of the electric field v/s distance curve, is thus much lower for the same peak electric field (and hence the same breakdown voltage) than the case of a flat electric field profile across the JTE. The JTE scheme drops the blocking voltage across multiple junctions in series and thus even when the peak electric field at each junction is kept the same, the JTE has a jagged sub-optimal field profile. A constant-doped JTE also has a non-uniform field profile and grading the JTE dose to reduce the spatial dose profile non-linearly from the anode edge outward can smoothen the electric field profile as desired. However, fabricating such a graded dose JTE will require an accurate control of JTE masking and implant, which can be difficult for wide bandgap devices where dopants are not easily diffused. The spaced-modulated JTE scheme emulates the ideal graded JTE dose in a quantized fashion but it also shows a sub-optimal jagged electric field profile. The space-modulated JTE is more sensitive to lithography than regular JTE and is more sensitive to the implant dose than floating field rings. However, the space-modulated JTE would typically need a smaller termination region.

Floating field rings can be created along with a p+ implant (at least one of which is typically already present). Traditional JTE scheme requires special JTE implants but space-modulated JTEs can be made with any pwell-type implant by using the right or proper space-modulation. All the floating field ring and JTE termination regions have multiple reverse biased pn junctions that lead to multiple field peaks, except in the case of a gradual space modulated JTE that will need a grayscale mask or bevel etching to implement. Further, the existing edge-termination schemes occupy chip area beyond the active current carrying region and cause an area overhead in typical Silicon Carbide (SiC) diodes. In order to reduce the area overhead, it is desirable to reduce the area occupied by the edge-termination structures while maintaining the field termination capability.

Based on the recognition of the need for reducing the area for the edge-termination structures, the disclosed technology provides an approach using a 3D electric field coupling to yield a desired optimum electric filed profile in the termination region. The proposed approach creates an effective continuous reduction in JTE dose away from the anode with only one JTE implant by using a 3-D design. The JTE region shaped as a finger (“JTE finger”) becomes narrower in width and spacing between the JTE fingers becomes wider as moving from the anode to the edge of the device. The 3-D field coupling in this “super-JTE” allows the flattening of the electric field profile across the edge termination region by optimizing the shape of the JTE fingers on the mask.

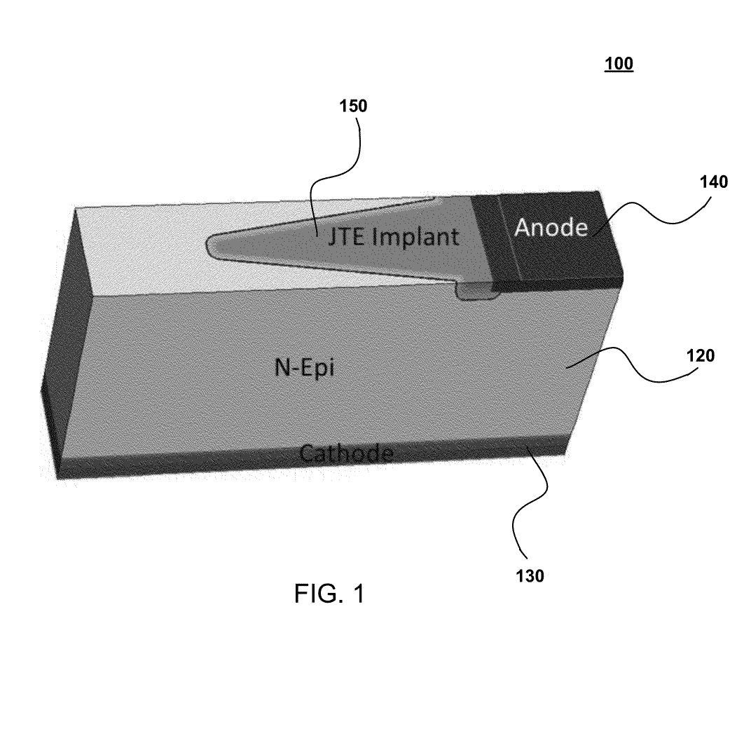

FIG. 1 shows an example of a power device 100 with the super-JTE structure. The power device 100 with the super JTE structure includes an epitaxial layer 120 having one side connected to a cathode 130 and another side connected to an anode 140. The power device 100 may further include a substrate, for example, a SiC wafer having a first conductivity type (e.g., an n-type substrate) on which the epitaxial layer 120 having the first conductivity type (e.g., n-type) is formed. This epitaxial layer 120 (which may comprise one or more separate layers) functions as a drift region of the power device 100. The device typically includes an active region which includes one or more power devices that have a p-n junction and/or a Schottky junction. The active region may be formed on and/or in the drift region. The active region acts as a main junction for blocking voltage in the reverse bias direction and providing current flow in the forward bias direction.

The power device 100 has a JTE region 150 that is adjacent the active region. One or more power devices may be formed on the substrate, and each power semiconductor device may have its own edge termination. After the substrate is fully formed and processed, the substrate may be diced to separate the individual edge-terminated power devices. In many cases, the power devices on the substrate will have a unit cell structure in which the active region of each power device includes a large number of individual devices that are disposed in parallel to each other and that together function as a single power device. Although not shown in FIG. 1, the power device 100 is provided with a doping region such as p-well and n+ implants already existing in BCD processes for the active cell and thus, can achieve a flat electric field profile across the JTE region. In some implementations, at least a part of the p-well is located under the anode 140.

The JTE region 150 has a part implanted with p-well concentration and another part having the n-epi concentration. In some implementations, a width of the JTE region is 10 um, similar or same as epi thickness, plus a field stop region. As shown in FIG. 1, the width of JTE implant region 150 reduces from an edge of the anode 140 outwards, thus “simulating” space modulation of JTE without creating series junctions to drop voltage. The 3D electric field coupling creates a super junction effect that can smooth out the electric field. The ideal function of JTE narrowing is not linear, but is gradual, and should be optimized to achieve breakdown as close to the ideal breakdown voltage as possible. For example, in some embodiments, the instantaneous slope of the tapering (first derivative) may be a small angle near the anode 140, e.g., zero degrees, and may linearly increase moving away from the anode 140, such that at the far end, the derivative angle may be 90 degrees. In some embodiments, the tapering may be mathematically represented as Ax^{b}, where A is a positive number, x represents distance away from the anode 140 and b is a rational number greater than 1.

In some embodiments, the JTE design has gradually lowering p-concentration in the JTE region 150 towards the periphery of the chip. In some implementations, the JTE region 150 can have any dose as long as the relative spacing of p and n regions is chosen to deplete both p and n portions of the termination region before onset of breakdown. The 3D electric field profile in this super-junction JTE, when designed properly, can give a near-flat electric field profile, thus allowing for a smaller termination region.

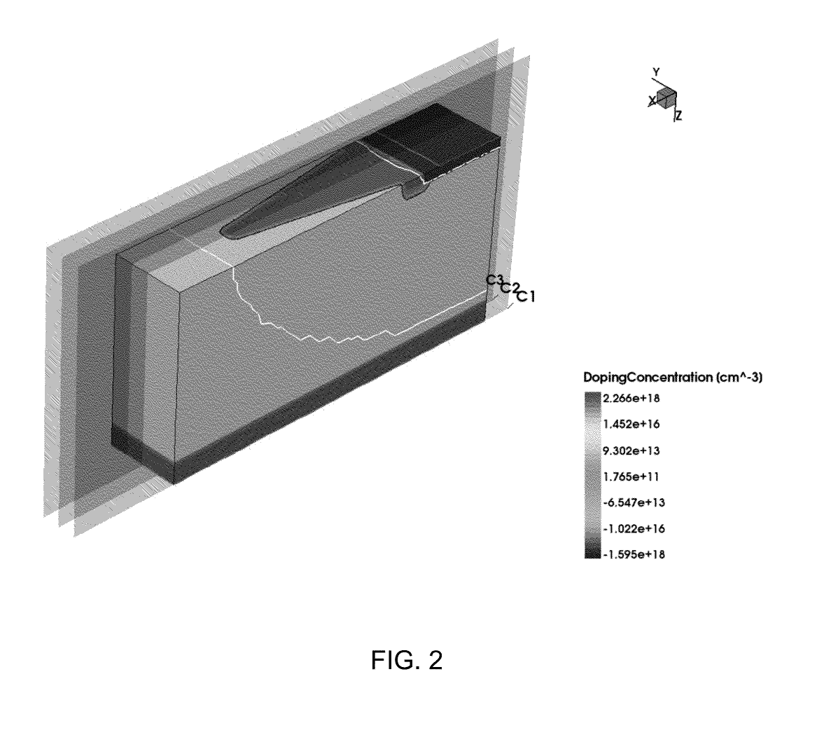

The gradual decrease in p-concentration of the super-JTE structure can be simulated by a 3-D design where the JTE region will get narrower towards the periphery of the chip. FIGS. 2 to 4 show various simulation results of a super-JTE structure.

FIG. 2 shows three cut planes C1 to C3 from the device structure used for TCAD simulation. The cut plane C1 is taken along farthest p-region, the cut plane C3 is taken along narrowest p-region, and the cut plane C2 is taken between the cut planes C1 and C3.

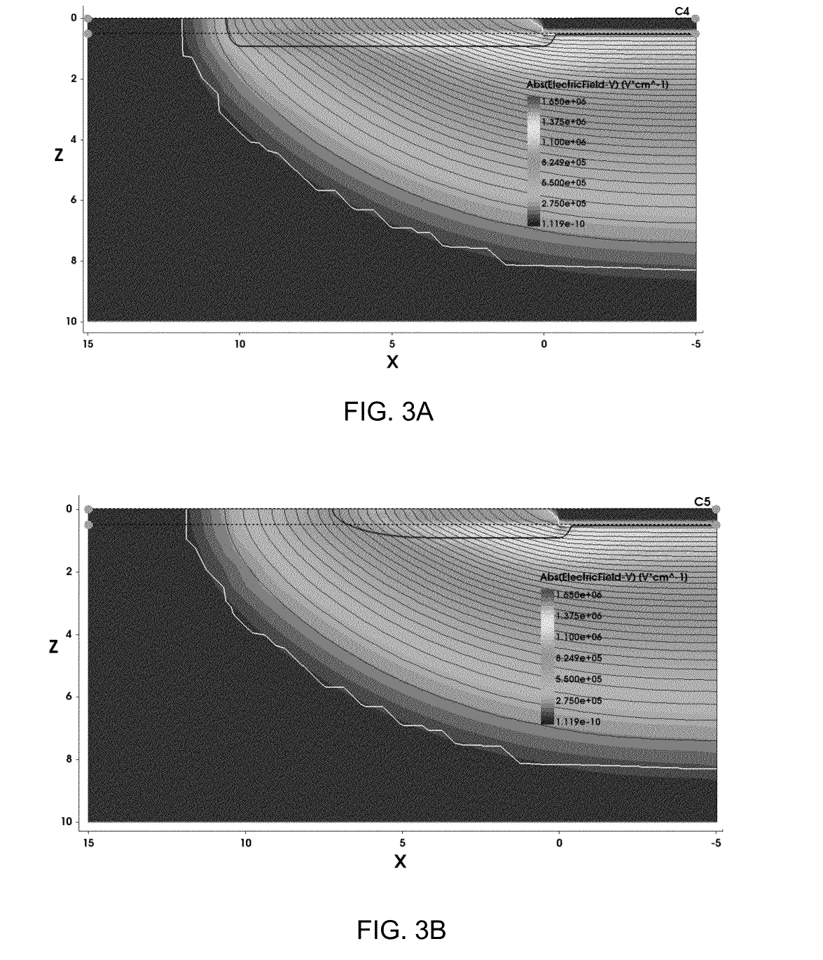

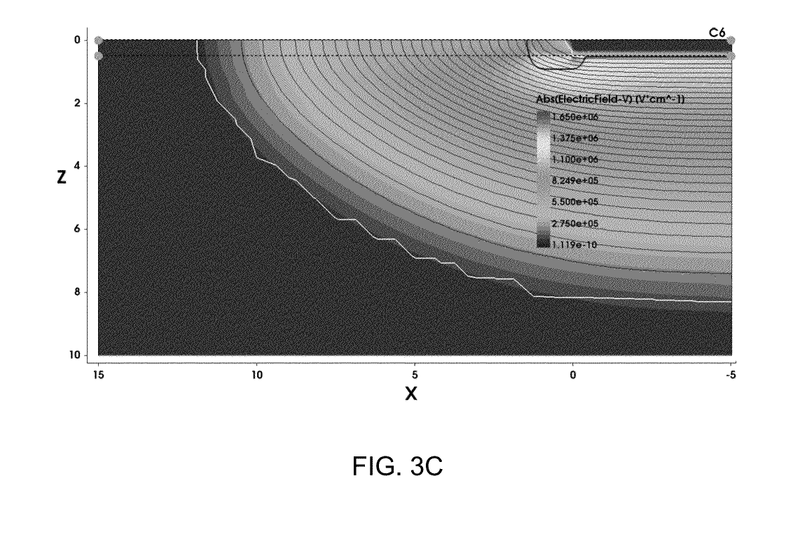

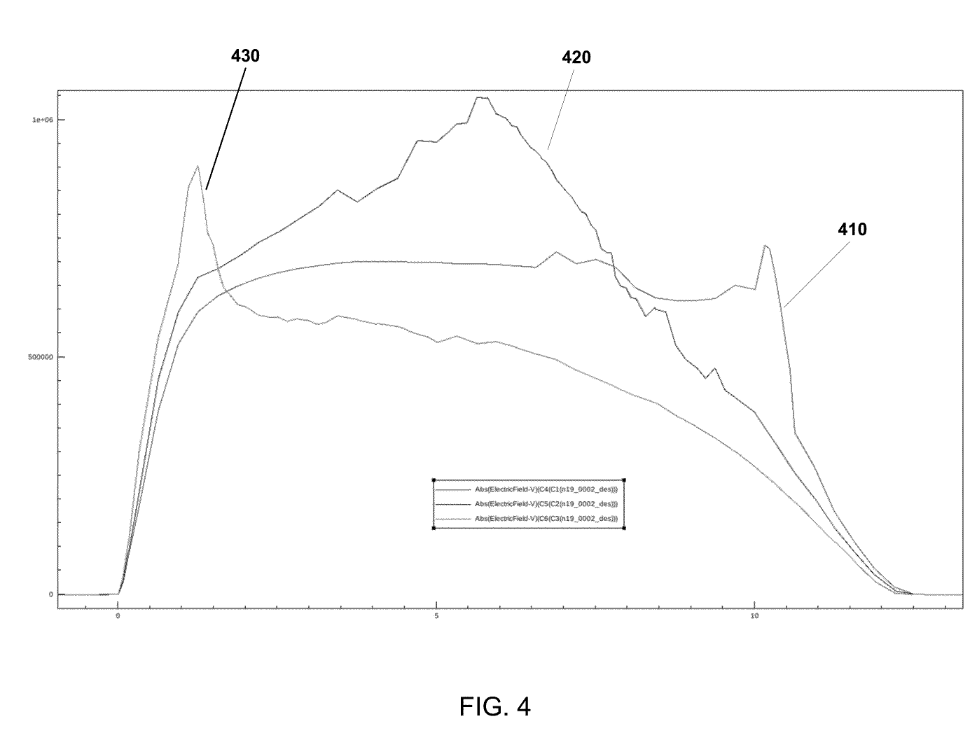

FIGS. 3A, 3B and 3C show respective simulations for the cut planes C1 to C3 of FIG. 2, and FIG. 4 shows a graph of a surface electric field along the cut planes C1 to C3 of FIG. 2. The different colors are used to indicate different ranges of doping concentrations (in FIG. 2) or electric fields (in FIG. 3A, 3B, 3C and FIG. 4). Referring to FIG. 4, at an anode surface along the cuts C1 to C3 of FIG. 2, the graph 410 bisects a JTE finger, thus has a peak farthest from anode, the graph 430 bisects the spacing between JTE fingers, and the graph 420 is between the graphs 410 and 430. Accordingly, the electric field peaks for C1, C2 and C3 also vary. The peaks can be smoothed by a non-linear JTE profile. In this simulation, the JTE implant width is reduced linearly towards the periphery and the electric field profile is flattened considerably. Using a higher order power function for the JTE implant periphery, electric field can be further smoothened, which allows to reduce the length of termination region to ˜2 times the epitaxial thickness, compared to termination region ˜5 times the epitaxial thickness that is commonly used. This will require JTE implant dose to be chosen specifically to achieve maximum blocking voltage.

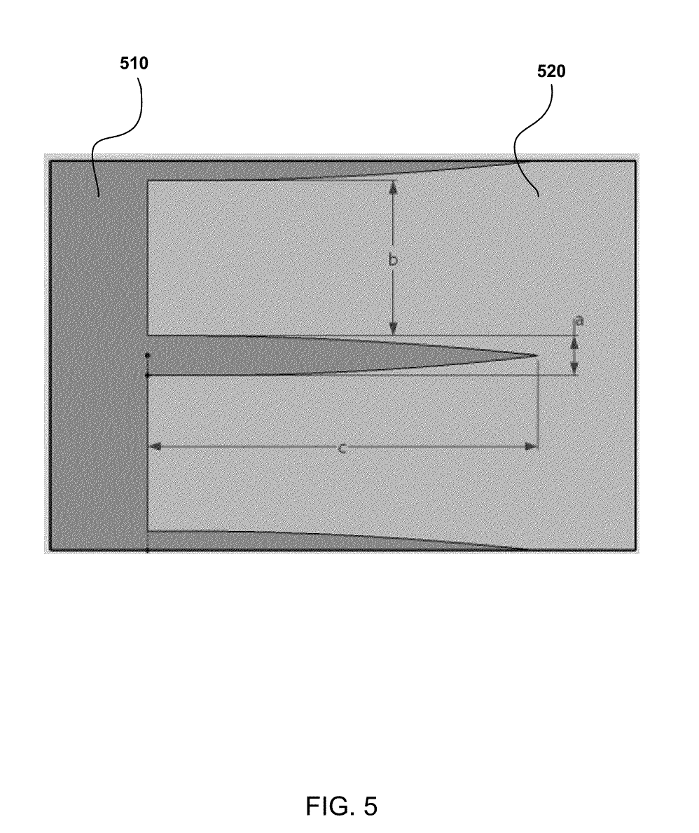

FIG. 5 shows a top view of another example of a super-JTE structure. The top view shows the p-well region 510 and the n-epi region 520. In the modified version of the super-JTE structure shown in FIG. 5, “a” is the maximum width of the JTE implanted region and “a+b” is the pitch. Further, “c” would ideally be approximately the width of the epi-layer but practically could be more. The super-JTE is designed to accommodate a given implant dose by scaling the ratio of implanted JTE region “a/(a+b)” for charge balance. As compared to the super-JTE structure of FIG. 1, an optimum JTE dose in FIG. 5 is approximately “(a+b)/a” times the dose of the example of FIG. 2. Therefore, in principle, it is possible to choose the dimensions “a” and “b” such that a wide window of JTE implant doses can be made optimum for the super-JTE structure. In the case of a SiC MOSFET, the p-well implant typically has much higher dose than the optimum JTE dose. By using super-JTE, it is possible to use the existing p-well implant for JTE, thus reducing an implant. By optimizing the JTE implant doses through the dimensions “a” and “b,” a dedicated JTE dose is not necessary and existing implants in the device could be used. In some implementations, JTE region at the furthest extent of the chip can be more rounded.

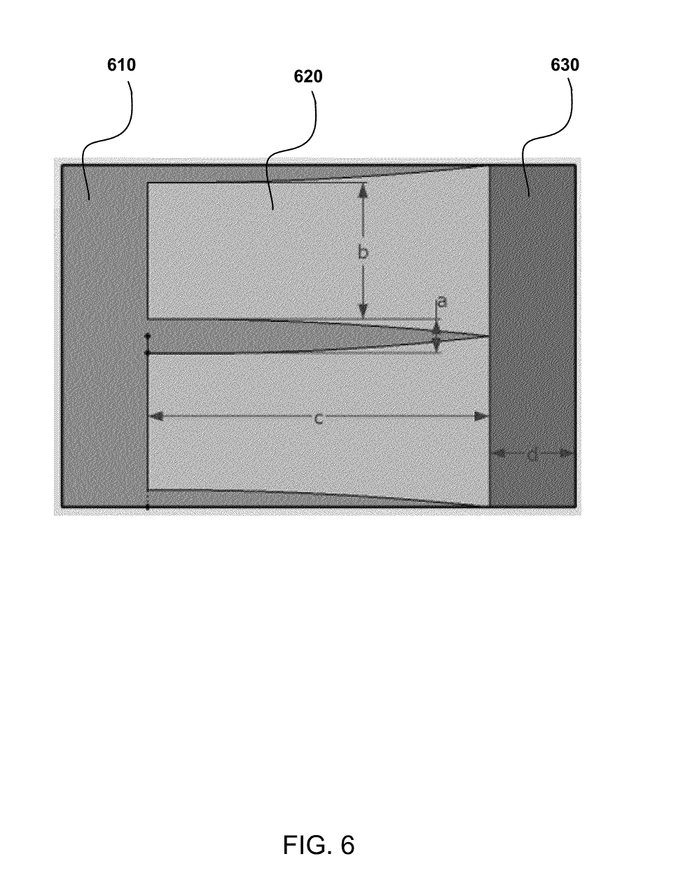

FIG. 6 shows a top view of yet another example of a super-JTE structure. Reference numbers 610, 620 and 630 show p-well region, n-epi region, and n+ field stop region, respectively. As in FIG. 5, “a” is the maximum width of the JTE implanted region, “a+b” is the pitch, and “c” would ideally be approximately the width of the epi-layer, but practically could be more. Further, the dimension “d” is a width of the n+ field stop region 630. The proportion of the p-well region 610 to the n-epi region 620 in 3D-JTE starts out as “a/(a+b)” and reduces towards the periphery of the device. The reduction of the proportion continues as the p-well region 610 defined between n-epi regions 620 has a narrowing width from “a” to 0 and eventually reaches a point there is an n+ implanted ring of width “d.” This creates a 3-dimensional electric field profile in the JTE region which, with the right shape of junction between p-well and n-epi, can flatten the electric field. Finding the right shape of the junction here is computationally intensive but once calculated or optimized by DOE and drawn on mask, can be repeatedly used with ease for device fabrication. In some implementations, the ideal shape will be different at device edges and rounded device corners. Even a linear decrease in p-well concentration with JTE width will give, as shown in FIG. 4, substantially flatter electric field profile than traditional JTE.

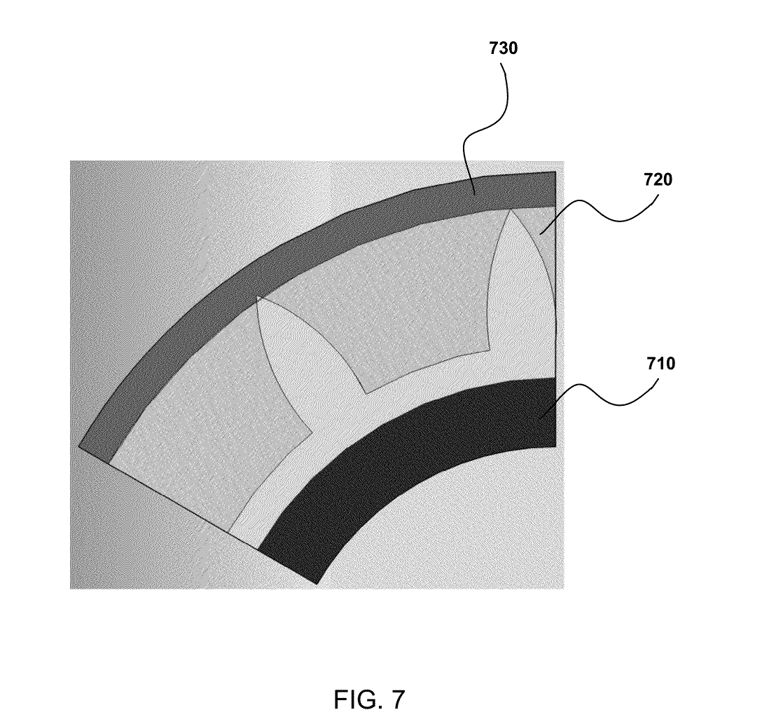

FIG. 7 shows an exemplary JTE design for corner regions. The top view of the corner regions shows a p-well region 710 in blue (different blue region showing different electric field), a n-epi region 720 in orange, a n+ region 730 in red. In corner regions, proportional p area falls faster towards the periphery if the same shape of p-well extension as edges is used, so the shape is modified to keep the same proportional p area v/s distance as at the edges. The optimum variation in proportional p-well area is different for corners but that effect is negligible as long as corner radius is many times epi thickness.

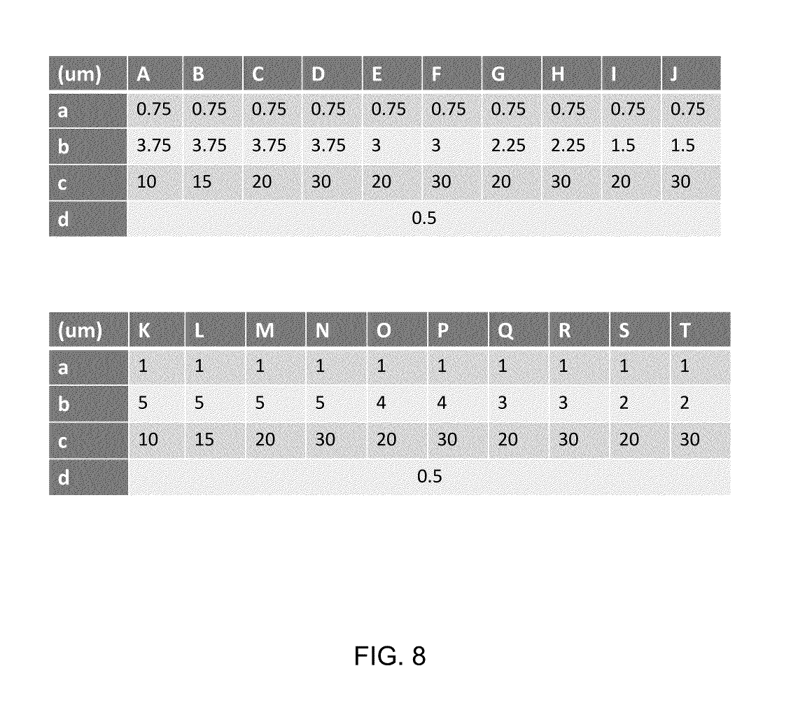

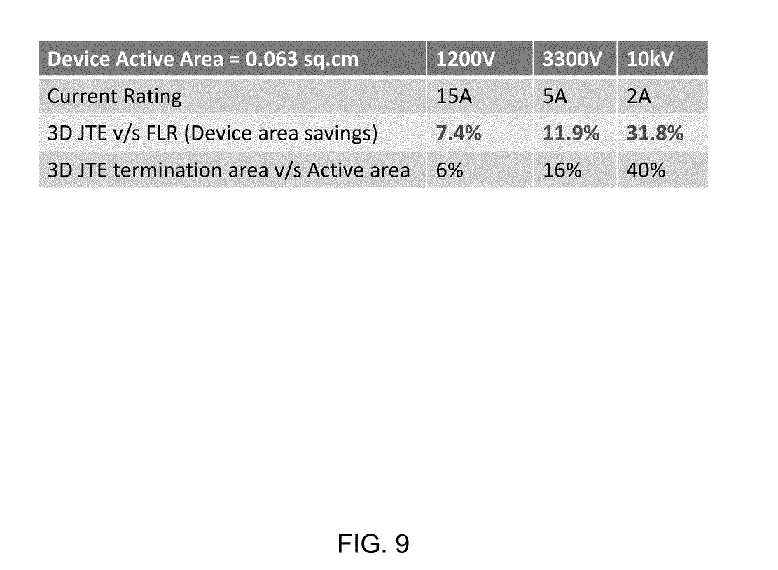

FIG. 8 shows various test designs and FIG. 9 shows the comparison of chip savings of 3D JTE v/s floating filed rings. In testing the elements, PN diodes are fabricated with p+ within the p-well tub forming the anode and splits as in FIG. 8 for the edge-termination. The shape of the p-well termination regions can be linear, but is better as increasing power law curves. Referring to FIG. 9, the super-JTE design can save approximately 7.5% of the chip area for a 1200V 15 A and 32% for a 10 kV 2 A device when compared to a typically used edge-termination scheme. Its advantage increases as die size reduces and as blocking voltage increases. Further, this 3D-JTE scheme retains the sensitivity of JTE performance to surface charge.

The JTE technology described in the present document could be incorporated into various semiconductor devices such as power transistors. The power transistors may use silicon or Silicon Carbide (SiC) substrates. Silicon carbide (SiC) semiconductor materials can exist in various crystalline forms and can be used to construct a range of SiC based circuits and devices. In comparison with the commonly used silicon, SiC materials possess properties such as a wide bandgap structure and higher breakdown field. These properties make SiC materials attractive for a wide range of circuits and applications including high power electronics.

Implementations of the suggested super-JTE scheme can produce FET devices with improved performance of structures. A field-effect transistor (FET) is a transistor that uses an electric field to control the shape and in turn the conductivity of a channel of one type of charge carrier in a semiconductor material. FETs are unipolar transistors that involve single-carrier-type operation. FETs can be structured to include an active channel through which majority charge carriers, e.g., such as electrons or holes, flow from a source to a drain. The main terminals of a FET include a source, through which the majority carriers enter the channel; a drain, through which the majority carriers leave the channel; and a gate, the terminal that modulates the channel conductivity. For example, source and drain terminal conductors can be connected to the semiconductor through ohmic contacts. The channel conductivity is a function of the potential applied across the gate and source terminals.

In some implementations, an exemplary silicon carbide metal insulator semiconductor field effect transistor (MOSFET) device can be designed to include a super-JTE structure. The device can include a base structure including a SiC substrate configured between a drain contact (e.g., drain electrode) and a SiC epitaxial layer-N. A region of the SiC epitaxial layer-N can be configured to provide a top surface having the super-JTE structure. In some implementations, the first MOSFET lot has epitaxial doping of ˜1×10¹⁶ targeting ˜1600V BV. MOSFET body contact has a p+ implant which will require much finer spacing to be used for 3D JTE. The MOSFET body has a p-well implant with average doping ˜3×10¹⁸ and 0.5 um deep, which can be used for 3D JTE. The equivalent dose here is ˜1.5×10¹⁴, which is ˜6 times the ideal single zone JTE dose (˜2.5×10¹³). So, in the design with 1.5×10¹⁴ dose, p-area proportion (a/(a+b)) in the termination region at anode boundary should be ˜⅙ and reducing outwards. Also, “a” and “b” should be small enough that the termination region is completely depleted and 3-D JTE effects take over well before significant impact ionization and avalanche effects. Reduction in p-area proportion needs to be faster than linear. A power law (parabolic or higher power) can be followed too, with corner smoothing.

The disclosed techniques can be advantageously used to improves either the area efficiency and hence cost, e.g., compared to other JTE, field rings etc., adds much lesser fabrication cost and complexity, e.g., compared to implant through grayscale mask. Accordingly, implementations of the present technology can reduce the cost of power devices. In addition, the disclosed techniques allow the JTE dose to be selected to match pre-existing implants, obviating the need for a dedicated JTE implant. Among other advantages, the disclosed technology can be used to provide good termination area efficiency without added process complexity (implants or mask steps).

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A semiconductor device, comprising:
a junction termination extension (JTE) region that is defined by a part with gradually reducing width extending towards a periphery of the semiconductor device.

2. The semiconductor device of claim 1, wherein the gradually reducing width is defined by a non-linear tapering towards the periphery.

3. The semiconductor device of claim 1, wherein a first doping charge of the JTE region is opposite to that of a doping charge of an epi region of the semiconductor device.

4. The semiconductor device of claim 1, wherein the gradual reducing is defined by a linear tapering towards the periphery or an optimized non-linear tapering function that maximizes the breakdown voltage

5. The semiconductor device of claim 1, wherein the gradual reducing results in a lowering of average charge at a particular distance from an edge of an anode of the semiconductor device, wherein a relation between the average charge and the particular distance is a continuously decreasing function of the particular distance.

6. The semiconductor device of claim 1, wherein a substrate of the semiconductor device comprises Silicon Carbide (SiC).

7. A semiconductor device, comprising:
a substrate;
a cathode;
an anode
an epitaxial layer formed over the substrate and having a first conductivity, the epitaxial layer including different portions electrically connected to the cathode and the anode, respectively; and
a JTE region formed over the epitaxial layer and extending away from the anode, the JTE region having a decreasing width as being away from the anode.

8. The semiconductor device of claim 7, further comprises:
a doping region having a second conductivity and located in the epitaxial layer to be in an electrical contact with the cathode.

9. The semiconductor device of claim 7, wherein:
the JTE region has a part with gradually lowering doping concentration toward a periphery of the semiconductor device.

10. The semiconductor device of claim 7, wherein the substrate includes SiC.

11. The semiconductor device of claim 7, wherein the JTE region provides a substantially flat electric field profile.

12. The semiconductor device of claim 7, wherein the JTE region has a part having the first conductivity and another part having a second conductivity.

13. The semiconductor device of claim 7, wherein the JTE region allows electric fields at a surface of the anode to have peaks at locations differently located from an edge of the anode.

14. The semiconductor device of claim 7, further comprising a field stop region formed over the epitaxial layer and located at a periphery of the semiconductor device.

15. A semiconductor device, comprising:
a substrate;
an epitaxial layer formed over the substrate and having a first conductivity;
a doping region formed in the epitaxial layer and having a second conductivity with a first implant dose; and
a JTE region formed over the epitaxial layer and having a second implant dose, the second implant dose determined based on the first implant dose.

16. The semiconductor device of claim 15, wherein the second implant dose is obtained by scaling the first implant dose based on a dimension of the JTE region.

17. The semiconductor device of claim 16, wherein the dimension of the JTE region includes a width or a pitch.

18. The semiconductor device of claim 15, wherein the JTE region has a part with decreasing width as being away from the doping region.

19. The semiconductor device of claim 15, wherein the JTE region has a gradually lowering doping concentration as being away from the doping region.

20. The semiconductor device of claim 15, further comprising:
a field stop region formed over the epitaxial layer and located at a periphery of the semiconductor device.
